(19) United States
(12) Patent Application Publication
(10) Pub. No.: US 2021/0136952 A1
(43) Pub. Date: May 6, 2021

(54) COMPUTER SYSTEM HAVING A COOLING SYSTEM FOR AN EXPANSION COMPONENT

(71) Applicant: Fujitsu Client Computing Limited, Kawasaki (JP)

(72) Inventors: Michael Riebel, München (DE); Frank Schubert, München (DE)

(21) Appl. No.: 17/088,679

(22) Filed: Nov. 4, 2020

(30) Foreign Application Priority Data
Nov. 6, 2019 (DE) 102019129928.4

(51) Int. Cl. H05K 7/20; G06F 1/20; G01K 7/00; G01R 19/00

(52) U.S. Cl. CPC H05K 7/20209; H05K 7/20136; G01K 2217/00; G01K 7/00; G01R 19/0092; G06F 1/206

(57) ABSTRACT

A computer system includes a system board, at least one expansion component detachably mounted on the system board, wherein the expansion component can be supplied with an electric voltage via the system board, a cooling system having an adaptable cooling performance for cooling the expansion component, a measuring device, and an evaluation device, wherein the measuring device is configured to measure electric current obtained by the expansion component during ongoing operation of the computer system, and provide electricity measurement information based thereon to the evaluation device, and the evaluation device is configured to determine a temperature behavior of the expansion component on the basis of the electricity measurement information provided by the measuring device and adapt the cooling performance of the cooling system depending on the determined temperature behavior of the expansion component.

### TECHNICAL FIELD

This disclosure relates to a computer system having a cooling system for an expansion component as well as a method of adapting a cooling performance of a cooling system of a computer system.

### BACKGROUND

In computer systems, components, in particular power-hungry expansion components, generate waste heat during ongoing operation, which needs to be dissipated via a cooling system so that the computer system and its components remain below a critical temperature and are not damaged. Generally, an evaluation device is provided in the computer system, which determines a temperature behavior of the waste heat-generating components and adapts the cooling performance of the cooling system depending on the determined temperature behavior. The temperature behavior is often detected via one or more temperature sensors arranged within the computer system. Corresponding sensor signals are supplied to the evaluation device, which adapts the cooling performance of the cooling system. As an alternative or in addition hereto, the components of the computer system provide temperature information to the evaluation device from which the evaluation device may conclude the corresponding temperature behavior.

Such approaches, however, have the disadvantage that in particular in operational situations having high power consumption of expansion components arranged for special functionalities, these are working to capacity such that corresponding temperature information or such signals are often suspended so that corresponding temperature information is at least temporarily not supplied to the evaluation device. Generated waste heat of the working components, however, is particularly critical specifically in such operational situations of high performance. For lack of informative temperature information, there is consequently the risk that the cooling performance of the cooling system is only adapted insufficiently to cool the computer system sufficiently. To avoid this risk in conventional computer systems, the cooling performance, on the other hand, is often set to be higher than required in the respective operation. This causes not least a high noise level of a cooling system in the computer system or an unnecessary power consumption of the cooling system.

It could therefore be helpful to provide a computer system as well as a method that enable an improved adaptation of a cooling performance of the cooling system in different possible operational situations, but are nevertheless easy to implement.

### SUMMARY

We provide a computer system including a system board, at least one expansion component detachably mounted on the system board, wherein the expansion component can be supplied with an electric voltage via the system board, a cooling system having an adaptable cooling performance for cooling the expansion component, a measuring device, and an evaluation device, wherein the measuring device is configured to measure electric current obtained by the expansion component during ongoing operation of the computer system, and provide electricity measurement information based thereon to the evaluation device, and the evaluation device is configured to determine a temperature behavior of the expansion component on the basis of the electricity measurement information provided by the measuring device and adapt the cooling performance of the cooling system depending on the determine temperature behavior of the expansion component.

We also provide a method of adapting a cooling performance of a cooling system of a computer system, wherein at least one expansion component is detachably mounted on a system board of the computer system, the expansion component is supplied with electric voltage via the system board during ongoing operation of the computer system, obtains electric current, and is cooled via the cooling system, the method including: measuring the electric current obtained by the expansion component during ongoing operation of the computer system by a measuring device; providing electricity measurement information based on the measured current by the measuring device to an evaluation device; determining a temperature behavior of the expansion component on the basis of the electricity measurement information provided by the measuring device by the evaluation device; and adapting the cooling performance of the cooling system depending on the determined temperature behavior of the expansion component by the evaluation device.

### BRIEF DESCRIPTION OF THE DRAWINGS

FIG. 1 is a schematized representation of an example of a computer system.

FIG. 2 is a schematized flow chart of an example of a method of adapting a cooling performance of a cooling system of a computer system. List of Reference Numerals 1 computer system 2 system board 3 expansion component 4 cooling system 5 measuring device 6 evaluation device 7 measurement signal line 8 control signal line 9 information signal line I current U voltage S1-S7 method steps

### DETAILED DESCRIPTION

Our computer system has a system board and at least one expansion component detachably mounted on the system board. The expansion component can be supplied with an electric voltage via the system board. The expansion component provides a certain functionality to the computer system. Via the expansion component, the computer system, for example, is expandable with certain functions. Supplying the expansion component via the system board with an electric voltage has the effect that the expansion component does not require any separate electric voltage supply. The expansion component is detachably mounted on the system board. The expansion component, for example, is removed from the system board when the corresponding functionality is not needed or another expansion component is intended to be employed on the system board. The expansion component, for example, is a so-called m.2 component mounted on a corresponding expansion area on the system board. The expansion component, for example, is an m.2 SSD component for data storage.

Our computer system further has a cooling system having an adaptable cooling performance for cooling the expansion component. The cooling system, for example, has one or more fans having an adaptable fan speed for adapting the cooling performance. Alternatively, or in addition, the cooling system is implemented also in another manner.

Furthermore, the computer system has a measuring device as well as an evaluation device. The measuring device is arranged (configured) to measure electric current obtained by the expansion component during ongoing operation of the computer system, and to provide electricity measurement information (current measurement information) based thereon to the evaluation device. The evaluation device is arranged to determine a temperature behavior of the expansion component on the basis of the electricity measurement information provided by the measuring device and to adapt the cooling performance of the cooling system depending on the determined temperature behavior of the expansion component.

Such a computer system has the advantage that a temperature behavior of the expansion component can be determined regardless of temperature sensor signals or regardless of temperature information, which have to be provided to the evaluation device via the expansion component itself. A temperature behavior of the expansion component thus can be determined regardless of the fact whether one or more temperature sensors are arranged in the computer system or whether or not the expansion component provides one or more signals for providing corresponding temperature information. In particular with different expansion components that can be detachably or exchangeably (modularly) mounted on the system board, this has the advantage that an adaptation of the cooling performance is not dependent on whether or not a corresponding expansion component delivers the required information.

The computer system is arranged such that a temperature behavior of the expansion component is advantageously determined from electricity measurement information which in turn is determined by measuring the electric current obtained by the expansion component. The computer system takes advantage of the fact that a power loss or waste heat of the expansion component is directly proportional to the current obtained by the expansion component at a certain voltage during ongoing operation.

The computer system thus enables the temperature behavior of the expansion component to be detected which itself is robust against failures/absence of the provision of temperature information by the expansion component, whereby the cooling performance of the cooling system can be adapted reliably. In this way, the computer system guarantees in any operational situation a sufficient cooling of the waste heat-generating expansion component. Furthermore, the cooling performance of the cooling system can be adapted to any operational situation of the computer system in an improved manner, without having to overproportion or over-dimension the cooling performance of the cooling system. An unnecessary noise development and an unnecessary cooling performance of the cooling system, respectively, thus are avoided.

In representative examples of the computer system, the measuring device is configured such that a measurement of the electric current obtained by the expansion component during ongoing operation of the computer system is performed in a supply path electrically connected upstream of the expansion component. The supply path is in particular a path between the current/voltage supply and the expansion component. This has the effect that the electric current obtained by the expansion component can be measured in a simple way without having to involve the expansion component itself into this measurement process. In this way, the expansion component can be kept simple. Moreover, this has the advantage that a measurement of the electric current of the expansion component for various expansion components of different functionalities is performed in the same way. In particular, in expansion components that are detachable from the system board, expansion components can be exchanged without a corresponding electricity measurement having to be adapted or changed. Providing signals or information through the expansion component for measuring the electric current obtained by the expansion component is not necessary. Advantageously, the measuring device is arranged in this manner to perform a measurement regardless of the functionality of the expansion component and separately from the expansion component in the supply path of the expansion component. The measuring device, for example, comprises an electric measuring resistor for electricity measurement. This allows a simple electricity measurement and keeps the implementation effort low.

The measuring device and/or the evaluation device may be integrated as onboard components on the system board. This enables a simple integration of the functionalities on the system board without having to provide additional devices or components separately from the system board (apart from the expansion component). Rather, the system board advantageously is configured such that the measuring device and/or the evaluation device can be accessed as configured/integrated components within the system board. This also simplifies implementation of the computer system, whereupon a detachable expansion component is merely connected to the system board, and the system board is arranged to detect the temperature behavior of the expansion component via an explained measurement by the measuring device.

The evaluation device may be a baseboard management controller (BMC) or functionally integrated within a baseboard management controller. This has the advantage that an evaluation of the provided electricity measurement information for determining a temperature behavior of the expansion component as well as an adaptation of the cooling performance of the cooling system depending on the determined temperature behavior can be performed by a component already provided for the latter purposes. This, as well, simplifies the implementation additionally.

The expansion component may be arranged to provide temperature information to the evaluation device, wherein the evaluation device is arranged to determine the temperature behavior of the expansion component on the basis of the temperature information provided by the expansion component, and to adapt the cooling performance of the cooling system depending on the determined temperature behavior of the expansion component. The expansion component, for example, is arranged to provide a signal to the evaluation device including corresponding temperature information of the expansion component. The signal, for example, is generated in the expansion component or is produced via a temperature sensor that detects a temperature of the expansion component or in the environment of the expansion component and transfers a corresponding signal to the expansion component. Alternatively, a corresponding sensor signal may be directly provided to the evaluation device by the temperature sensor. This configuration represents a further possibility for the evaluation device to determine a temperature behavior of the expansion component and to adapt the cooling performance of the cooling system correspondingly.

The evaluation device may be configured to consider both the temperature information provided by the expansion component and the electricity measurement information provided by the measuring device to determine the temperature behavior of the expansion component. This has the advantage that the temperature behavior of the expansion component can be determined in an improved or possibly more precise manner, which results in an improved adaptation of the cooling performance of the cooling system.

Alternatively, the evaluation device may be arranged to determine the temperature behavior of the expansion component on the basis of the temperature information provided by the expansion component, if the temperature information is provided, and to determine the temperature behavior of the expansion component on the basis of the electricity measurement information provided by the measuring device, if the temperature information is not provided. In such examples, the evaluation device is thus configured to determine the temperature behavior alternatively either from temperature information provided directly by the expansion component, or from electricity measurement information provided by the measuring device. Such a configuration of the computer system allows the temperature behavior to be detected via the evaluation device, for example, in regular operation, on the basis of the temperature information provided by the expansion component. This is done, for example, by providing corresponding signals from the expansion component to the evaluation device. When the expansion component (temporarily) does not or no longer provide corresponding signals, the evaluation device is configured to refer to the electricity measurement information provided by the measuring device, and to determine the temperature behavior of the expansion component on the basis of the provided electricity measurement information.

In this way, the functionality of an adaptation of the cooling performance of the cooling system remains maintained on the basis of a detected temperature behavior of the expansion component, even if the expansion component does not or no longer provides corresponding temperature information. The evaluation device, for example, is furthermore configured such that the temperature behavior of the expansion component is again determined on the basis of the temperature information provided by the expansion component, once the corresponding temperature information is (again) provided by the expansion component. The evaluation device, for example, is furthermore configured such as to monitor the provision of temperature information by the expansion component.

The expansion component, for example, is arranged to provide temperature information in normal operation, and not to provide temperature information in an operation of an increased or maximum load. When there is a change between these operational situations, the corresponding configuration of the evaluation device thus has the advantage that it can switch from obtaining the temperature information by the expansion component to obtaining electricity measurement information by the measuring device to be able to continue to determine the temperature behavior of the expansion component despite of changed operational situations.

In the method, at least one expansion component is mounted detachably on a system board of the computer system, wherein the expansion component, during ongoing operation of the computer system, is supplied with electric voltage and obtains electric current via the system board, and is cooled via the cooling system.

In a first step, measuring of the electric current obtained by the expansion component during ongoing operation of the computer system is performed by a measuring device. In a further step, providing electricity measurement information (current measurement information) based on the measured current by the measuring device to an evaluation device is performed. In a further step, determining a temperature behavior of the expansion component on the basis of the electricity measurement information provided by the measuring device is performed by the evaluation device. In a further step, adapting the cooling performance of the cooling system depending on the determined temperature behavior of the expansion component is performed by the evaluation device.

Such a method achieves the same effects and advantages as already explained in conjunction with the computer system according to the first aspect above, to which reference is made at this point.

The expansion component may provide temperature information to the evaluation device, wherein the evaluation device determines the temperature behavior of the expansion component on the basis of the temperature information provided by the expansion component, and adapts the cooling performance of the cooling system depending on the determined temperature behavior of the expansion component. These measures have the advantage that the evaluation device performs a determination of the temperature behavior of the expansion component alternatively or complementarily to considering the electricity measurement information provided by the measuring device while considering the temperature information provided by the expansion component itself, and on the basis of this, carries out the adaptation of the cooling performance of the cooling system. In this way, the temperature behavior can be determined in an improved or selective manner depending on the operational behavior of the expansion component.

In diverse implementations or further developments of the method, the evaluation device determines the temperature behavior of the expansion component on the basis of the temperature information provided by the expansion component, if the temperature information is provided, and determines the temperature behavior of the expansion component on the basis of electricity measurement information provided by the measuring device, if the temperature information is not provided. These measures have the advantage that temperature information provided by the expansion component is referred to as a standard, which enables a simple implementation tailored to the expansion component. In the event of failure of providing the temperature information by the expansion component, reference is made, however, to the electricity measurement information by the measuring device, whereby the evaluation device can continue to determine the temperature behavior of the expansion component to adapt the cooling performance of the cooling system correspondingly.

If in an operational situation of the expansion component, for example, in an event of overload or maximum load, the provision of the temperature information by the expansion component fails, the evaluation device continues to detect the temperature behavior of the expansion component on the basis of the electricity measurement information provided by the measuring device. If the expansion component passes over to another operational state and, for its part, provides temperature information (again), the evaluation device again switches over to determine the temperature behavior of the expansion component on the basis of the temperature information provided again. In this way, a secure determination of the temperature behavior of the expansion component is performed in any operational situation of the expansion component.

Further developments or implementations, all of the explained aspects, structural features, advantages and effects of a computer system of the kind explained above are reflected in aspects, method features, measures, advantages and effects of a corresponding method of the kind explained above, and vice versa.

Our methods and systems will be explained in more detail on the basis of examples with the help of several drawings.

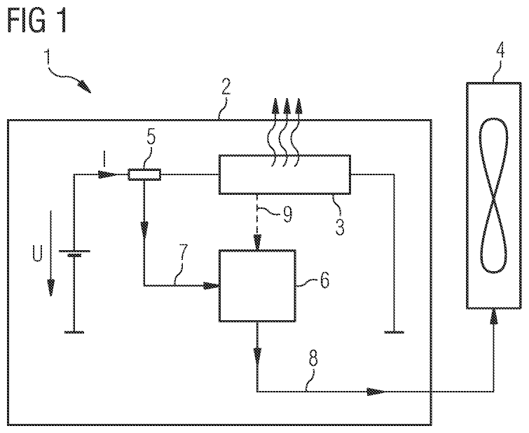

FIG. 1 shows a schematized representation of an example of a computer system 1 having a system board 2, an expansion component 3 and a cooling system 4. The expansion component 3 is mounted detachably on the system board 2. This means, that the expansion component 3 is not realized as an integral component of the system board 2, but is mounted on the system board 2 as an exchangeable component. The expansion component 3, for example, provides a certain functionality for expanding or upgrading the computer system 1 on the system board 2. The expansion component, for example, is an m.2 component, for example, an m.2 SSD component for storing data of the computer system 1. For the secure data storage, the expansion component, for example, performs storage encoding according to predefined encoding algorithms (and corresponding decoding), which may be very power-intensive. A corresponding mechanism, for example, is BitLocker.

During ongoing operation of the computer system 1, the expansion component 3 is supplied with electric voltage U via the system board 2 and thereby obtains electric current I. During ongoing operation, the expansion component 3 generates a certain amount of waste heat due to the consumption of electric power that is illustrated in FIG. 1 by undulated arrows at the expansion component 3. This waste heat is evacuated via the cooling system 4, whereby the expansion component 3 and the system board 2 of the computer system 1, respectively, are cooled. In the example according to FIG. 1, the cooling system 4 is a radial fan, the fan speed of which can be adapted to adapt the cooling performance. Alternatively, the cooling system 4 is implemented otherwise or has a plurality of fans.

On the system board 2, an evaluation device 6 is furthermore arranged, which in the example according to FIG. 1, for example, is configured as a baseboard management controller (BMC) or as part of a BMC. The evaluation device 6 controls the cooling system 4 via a control signal line 8 for adapting the cooling performance of the cooling system 4. The evaluation device 6, for example, predefines a certain fan speed of the cooling system 4 depending on the operational situation or operational behavior of the computer system 1. A temperature of the computer system 1 or components of the computer system 1, for example, is detected via temperature sensors (not explicitly represented). These temperature sensors, for example, provide sensor signals to the evaluation device 6, which detects a temperature behavior of the computer system 1 and, via the control signal line 8, performs an adaptation of the cooling performance of the cooling system 1 to cool the computer system 1 sufficiently in any operational situation. In the example according to FIG. 1, such temperature sensors, however, are optional.

To detect the temperature behavior especially of the expansion component 3, the system board 2 has a functionality that will be explained in more detail hereinafter.

During normal operation according to the example in FIG. 1, the expansion component 3 provides one or more signals including temperature information to the evaluation device 6 via an information signal line 9. Based on this temperature information, the evaluation device 6 detects a temperature behavior of the expansion component 3. The temperature information thus serves as a direct feedback to the evaluation device 6, whether or not the temperature of the expansion component 3 is critical. Depending on the temperature behavior detected on the basis of the temperature information, the evaluation device 6 adapts the cooling performance of the cooling system 4 correspondingly so that the expansion component 3 is cooled sufficiently. For the expansion component 3, for example, characteristic temperature ranges or a critical temperature that should not be exceeded to avoid overheating are stored in the evaluation device 6 or in other system components of the computer system 1, for example, within a BIOS. On the basis of this stored information, the evaluation device 6, in conjunction with the temperature information obtained by the expansion component 3, can perform an evaluation of the temperature behavior of the expansion component 3.

If the provision of temperature information by the expansion component 3, however, fails, since the expansion component 3, for example, is defective or in a state of increased or maximum load or overload, an evaluation of the temperature behavior on the basis of the temperature information by the evaluation device 6 is no longer possible since such information is no longer provided to the evaluation device 6. Such a situation occurs, for example, when the expansion component 3 carries out an encoding algorithm explained above and is used to capacity at 100% without having the possibility to give a corresponding feedback to the evaluation device 6 or the system board 2 on their temperature behavior. Without such temperature information, the evaluation device 6 can no longer evaluate, whether or not the expansion component 3 is still present in the system at all, not to mention, whether the expansion component 3 is within a stable and safe temperature range.

In such an example, for the safe operation of the computer system 1, the evaluation device 6 is forced to instruct the cooling system 4 via the control signal line 8 to produce increased cooling power. This, however, has the disadvantage that an unnecessarily high cooling performance is rendered if the expansion component 3 is in an uncritical temperature state or, for example, has been removed from the system board 2. In particular in the implementation of the cooling system 4 as a radial fan, this results in an unnecessarily increased noise level or an unnecessarily high cooling performance.

The configuration of the computer system 1 according to the example in FIG. 1, however, offers the evaluation device 6 yet another possibility. On the system board 2, a measuring device 5 is additionally integrated as an onboard component. In the example according to FIG. 1, the measuring device 5, for example, is a measuring resistor or comprises a measuring resistor for measuring the electric current I obtained by the expansion component 3. In the example according to FIG. 1, the measuring device 5 is configured in a supply path between the voltage source U and the expansion component 3, i.e., is electrically connected upstream of the expansion component 3. This allows the measuring device 5 to measure the electric current I obtained by the expansion component 3 independent of the expansion component 3 or a functionality of the expansion component 3. Via a measurement signal line 7, the measuring device 5 provides corresponding electricity measurement information to the evaluation device 6, independent of the expansion component.

The evaluation device 6 therefore takes advantage of the fact that waste heat or thermal power of the expansion component 3 is directly proportional to the supply current I, which the expansion component 3 obtains via its supply path from the voltage source U. The higher the current I, the higher a waste heat of the expansion component 3 must be assessed. In this way, the evaluation device 6 detects a temperature behavior of the expansion component 3 on the basis of the electricity measurement information provided by the measuring device 5 via the measuring signal line 7 without the need for providing temperature information at the information signal line 9. The evaluation device 6 can rather estimate the temperature behavior of the expansion component 3 solely from the electricity measurement information obtained via the measuring device 5, and can readjust the cooling performance of the cooling system 4 via the control signal line 8. If in a certain operational state, the expansion component 3 consumes high current I, the evaluation device 6 assumes on the basis of the detected electricity measurement information that high waste heat is present at the expansion component 3 or that high waste heat will occur at the expansion component 3 after a defined period of time since the expansion component 3 is in high power consumption. In such a situation, the evaluation device 6 increases the cooling performance of the cooling system 4.

If the expansion component 3 in another operational state consumes low current I, the evaluation device 6 assesses the temperature behavior of the expansion component 3 as being uncritical and reduces the cooling performance of the cooling system 4 via the control signal line 8.

In this way, the evaluation device 6, even without referring to temperature information of the expansion component 3 itself, can adjust the cooling system 4 merely from electricity measurement information of the measuring device 5 such that the computer system 1, in any operational situation, is cooled with respect to the expansion component 3, wherein an unnecessarily high cooling performance with the corresponding disadvantages is avoided.

If after a failure of providing temperature information by the expansion component 3 itself by the information signal line 9, provision of corresponding information is again performed, for example, when the expansion component 3 returns from a high load state or overload state into normal operation, the evaluation device 6 alternatively or complementarily to the electricity measurement information of the measuring device 5 evaluates the temperature behavior of the expansion component 3 again while considering the temperature information provided by the expansion component 3.

In alternative examples of the computer system 1 according to FIG. 1, a signalizing possibility between the expansion component 3 and the evaluation device 6 via the information signal line 9 is omitted. In such examples, an evaluation of the temperature behavior of the expansion component 3 via the evaluation device 6 is exclusively performed on the basis of the electricity measurement information provided by the measuring device 5.

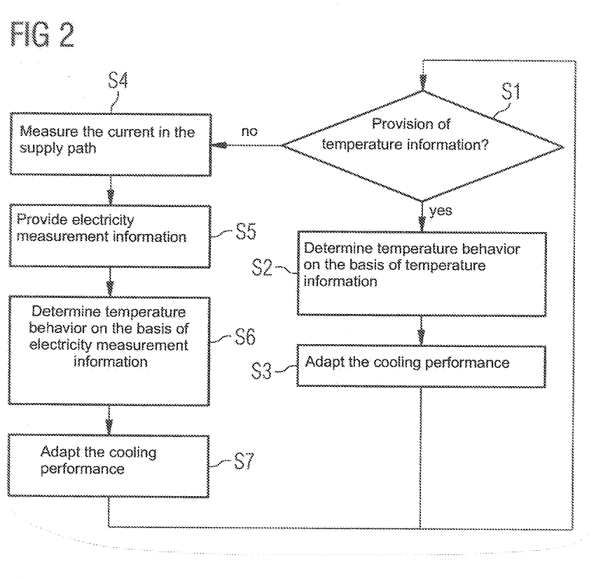

FIG. 2 shows a schematized flow chart of a method of adapting a cooling performance of a cooling system of a computer system. The method according to the example from FIG. 2, for example, is performed within the computer system 1 according to FIG. 1 or in alternative examples.

The method according to the example from FIG. 2 first starts in step S1, wherein it is checked whether or not the expansion component 3 provides corresponding temperature information (via the information signal line 9 according to FIG. 1). If the answer is YES, step 2 is performed according to the method, wherein, via the evaluation device 6, a temperature behavior of the expansion component 3 is determined on the basis of the provided temperature information. In a step S3, an adaptation of the cooling performance of the cooling system 4 is then performed to guarantee a sufficient cooling of the expansion component 3.

If, however, in step S1 of the method according to FIG. 2, it is determined that the expansion component 3 does not provide corresponding temperature information, the method switches to steps S4 to S7 which then are performed alternatively to steps S2 and S3.

In step S4, a measurement of the current I in the supply path between the voltage supply U and the expansion component 3 is performed via the measuring device 5, wherein in step S5, electricity measurement information is provided to the evaluation device 6 via the measuring device 5.

In step S6, the evaluation device 6 then determines a temperature behavior of the expansion component 3 on the basis of electricity measurement information provided by the measuring device 5.

In step S7, in analogy to step S3, an adaptation of the cooling performance of the cooling system 4 is performed by the evaluation device 6.

As an alternative to the example according to FIG. 2, steps S4 to S7 may also be performed in parallel to steps S2 and S3, even if the expansion component 3 provides corresponding temperature information. This has the advantage that a temperature behavior of the expansion component 3 can be detected redundantly or in an improved manner from different detection sources. Only when the expansion component 3 itself does not provide corresponding temperature information, steps S4 to S7 are performed separately from steps S2 and S3.

The explained examples and implementations have been selected merely illustratively.

1. A computer system comprising:
a system board;
at least one expansion component detachably mounted on the system board, wherein the expansion component can be supplied with an electric voltage via the system board;
a cooling system having an adaptable cooling performance for cooling the expansion component;
a measuring device; and
an evaluation device,
wherein the measuring device is configured to measure electric current obtained by the expansion component during ongoing operation of the computer system, and provide electricity measurement information based thereon to the evaluation device, and
the evaluation device is configured to determine a temperature behavior of the expansion component on the basis of the electricity measurement information provided by the measuring device and adapt the cooling performance of the cooling system depending on the determined temperature behavior of the expansion component.

2. The computer system according to claim 1, wherein the measuring device and/or the evaluation device are integrated on the system board as onboard components.

3. The computer system according to claim 1, wherein the evaluation device is a baseboard management controller or functionally integrated within a baseboard management controller.

4. The computer system according to claim 1, wherein the expansion component is configured to provide temperature information to the evaluation device, and
the evaluation device is configured to determine the temperature behavior of the expansion component on the basis of the temperature information provided by the expansion component, and adapt the cooling performance of the cooling system depending on the determined temperature behavior of the expansion component.

5. The computer system according to claim 4, wherein the evaluation device is configured to determine
the temperature behavior of the expansion component on the basis of the temperature information provided by the expansion component if the temperature information is provided, and
the temperature behavior of the expansion component on the basis of the electricity measurement information provided by the measuring device if the temperature information is not provided.

6. A method of adapting a cooling performance of a cooling system of a computer system,
wherein at least one expansion component is detachably mounted on a system board of the computer system, the expansion component is supplied with electric voltage via the system board during ongoing operation of the computer system, obtains electric current, and is cooled via the cooling system, the method comprising:
measuring the electric current obtained by the expansion component during ongoing operation of the computer system by a measuring device;
providing electricity measurement information based on the measured current by the measuring device to an evaluation device;
determining a temperature behavior of the expansion component on the basis of the electricity measurement information provided by the measuring device by the evaluation device; and
adapting the cooling performance of the cooling system depending on the determined temperature behavior of the expansion component by the evaluation device.

7. The method according to claim 6, wherein the measuring device and/or the evaluation device are integrated on the system board as onboard components.

8. The method according to claim 6, wherein the evaluation device is a baseboard management controller or is functionally integrated within a baseboard management controller.

9. The method according to claim 6, wherein the expansion component provides temperature information to the evaluation device, and
the evaluation device determines the temperature behavior of the expansion component on the basis of the temperature information provided by the expansion component, and adapts the cooling performance of the cooling system depending on the determined temperature behavior of the expansion component.

10. The method according to claim 9, wherein the evaluation device determines the temperature behavior of the expansion component on the basis of
the temperature information provided by the expansion component if the temperature information is provided, and
the electricity measurement information provided by the measuring device if the temperature information is not provided.
